(19) United States
(12) Patent Application Publication
(10) Pub. No.: US 2014/0273401 A1
(43) Pub. Date: Sep. 18, 2014

(54) SUBSTRATE LASER DICING MASK INCLUDING LASER ENERGY ABSORBING WATER-SOLUBLE FILM

(71) Applicants: Wei-Sheng LEI, San Jose, CA (US); Brad EATON, Menlo Park, CA (US); Aparna IYER, Sunnyvale, CA (US); Saravjeet SINGH, Santa Clara, CA (US); Madhava Rao YALAMANCHILI, Morgan Hill, CA (US); Ajay KUMAR, Cupertino, CA (US)

(72) Inventors: Wei-Sheng LEI, San Jose, CA (US); Brad EATON, Menlo Park, CA (US); Aparna IYER, Sunnyvale, CA (US); Saravjeet SINGH, Santa Clara, CA (US); Madhava Rao YALAMANCHILI, Morgan Hill, CA (US); Ajay KUMAR, Cupertino, CA (US)

(21) Appl. No.: 14/204,228

(22) Filed: Mar. 11, 2014

Related U.S. Application Data
(60) Provisional application No. 61/784,645, filed on Mar. 14, 2013.

(51) Int. Cl. H01L 21/78; H01L 21/67; H01L 23/544

(52) U.S. Cl. CPC H01L 21/78; H01L 23/544; H01L 21/67069
USPC 438/462; 257/620; 156/345.31

(57) ABSTRACT

Methods of dicing substrates having a plurality of ICs. A method includes forming a mask comprising a laser energy absorbing material layer soluble in water over the semiconductor substrate. The laser energy absorbing material layer may be UV curable, and either remain uncured or be cured prior to removal with a water rinse. The mask is patterned with a laser scribing process to provide a patterned mask with gaps. The patterning exposes regions of the substrate between the ICs. The substrate may then be plasma etched through the gaps in the patterned mask to singulate the IC with the laser energy absorbing mask protecting the ICs for during the plasma etch. The soluble mask is then dissolved subsequent to singulation.

### PRIORITY

This application is a Non-Provisional of, claims priority to, and incorporates by reference in its entirety for all purposes, the U.S. Provisional Patent Application No. 61/784,645 filed Mar. 14, 2013

### TECHNICAL FIELD

Embodiments of the present invention pertain to the field of semiconductor processing and, in particular, to masking methods for dicing substrates, each substrate having an integrated circuit (IC) thereon.

### BACKGROUND DESCRIPTION OF RELATED ART

In semiconductor substrate processing, integrated circuits (ICs) are formed on a substrate (also referred to as a wafer), typically composed of silicon or other semiconductor material. In general, thin film layers of various materials which are either semiconducting, conducting, or insulating are utilized to form the ICs. These materials are doped, deposited, and etched using various well-known processes to simultaneously form a plurality of ICs, such as memory devices, logic devices, photovoltaic devices, etc, in parallel on a same substrate.

Following device formation, the substrate is mounted on a supporting member such as an adhesive film stretched across a film frame and the substrate is “diced” to separate each individual device or “die” from one another for packaging, etc. Currently, the two most popular dicing techniques are scribing and sawing. For scribing, a diamond tipped scribe is moved across a substrate surface along pre-formed scribe lines. Upon the application of pressure, such as with a roller, the substrate separates along the scribe lines. For sawing, a diamond tipped saw cuts the substrate along the streets. For thin substrate singulation, such as <150 μm thick bulk silicon singulation, the conventional approaches have yielded only poor process quality. Some of the challenges that may be faced when singulating die from thin substrates may include microcrack formation or delamination between different layers, chipping of inorganic dielectric layers, retention of strict kerf width control, or precise ablation depth control.

While plasma dicing has also been contemplated, a standard lithography operation for patterning resist may render implementation cost prohibitive. Another limitation possibly hampering implementation of plasma dicing is that plasma processing of commonly encountered metals (e.g., copper) in dicing along streets can create product issues or throughput limits. Finally, masking of the plasma dicing process may be problematic, depending on, inter alia, the thickness and top surface topography of the substrate, the selectivity of the plasma etch, and removal of the mask selectively from the materials present on the top surface of the substrate.

### SUMMARY

Embodiments of the present invention include methods of masking semiconductor substrates for a laser dicing or hybrid dicing process including both laser scribing and plasma etching.

In an embodiment, a method of dicing a semiconductor substrate having a plurality of ICs includes forming a laser energy absorbing water-soluble mask over the semiconductor substrate. In exemplary embodiments, the mask material is capable of absorbing photon energy at the laser wavelength employed for scribing the IC while still retaining a sufficient degree of water solubility to facilitate easy removal of the mask following the dicing process. The mask is patterned with a laser scribing process to provide a patterned mask with gaps, exposing regions of the substrate between the ICs. The substrate is then plasma etched through the gaps in the patterned mask to singulate the ICs into chips.

In another embodiment, a system for dicing a semiconductor substrate includes a femtosecond laser; a plasma etch chamber, and a mask deposition module, coupled to a same platform.

In another embodiment, a method of dicing a substrate having a plurality of ICs includes forming a water-soluble mask, such as a laser photon-curable water-soluble polymer, over a front side of a silicon substrate. The ICs include a copper bumped top surface having bumps surrounded by a passivation layer, such as polyimide (PI). Subsurface thin films below the bumps and passivation include a low-K interlayer dielectric (ILD) layer and a layer of copper interconnect. The water-soluble mask, being photon-curable, is laser energy absorbing within at least the laser band which improves laser-scribed edge quality as the passivation layer, and subsurface thin films are patterned with a laser scribing process (e.g., femtosecond laser) to expose regions of the silicon substrate between the ICs. The silicon substrate is etched through the gaps with a deep silicon plasma etch process to singulate the ICs and the water-soluble mask, which may remain substantially uncured in regions not laser ablated is then wet processed to dissolve the material off of the passivation layer.

### BRIEF DESCRIPTION OF THE DRAWINGS

Embodiments of the present invention are illustrated by way of example, and not limitation, in the figures of the accompanying drawings in which:

FIG. 1 is a flow diagram illustrating a hybrid laser ablation-plasma etch singulation method employing a laser energy absorbing water-soluble mask, in accordance with an embodiment of the present invention;

FIG. 2 is a flow diagram illustrating a laser ablation singulation method employing a laser energy absorbing water-soluble mask, in accordance with an embodiment of the present invention;

FIGS. 3A and 3B are schematics illustrating differing levels of laser light coupling between a transparent mask and a laser energy absorbing water-soluble mask, in accordance with an embodiment of the present invention;

FIG. 4A illustrates a cross-sectional view of a semiconductor substrate including a plurality of ICs corresponding to operation 102 of the dicing methods illustrated in FIGS. 1 and 2, in accordance with an embodiment of the present invention;

FIG. 4B illustrates a cross-sectional view of a semiconductor substrate including a plurality of ICs corresponding to operation 103 of the dicing methods illustrated in FIGS. 1 and 2, in accordance with an embodiment of the present invention;

FIG. 4C illustrates a cross-sectional view of a semiconductor substrate including a plurality of ICs corresponding to operation 105 of the dicing method illustrated in FIG. 1, in accordance with an embodiment of the present invention;

FIG. 4D illustrates a cross-sectional view of a semiconductor substrate including a plurality of ICs corresponding to operation 107 of the dicing methods illustrated in FIGS. 1 and 2, in accordance with an embodiment of the present invention;

FIG. 5 illustrates a cross-sectional view of a laser energy absorbing water-soluble mask applied to over a top surface and subsurface thin films of a substrate including a plurality of ICs, in accordance with embodiments of the present invention;

FIG. 6 illustrates a block diagram of a tool layout for laser and plasma dicing of substrates with an integrated deposition module for in-situ application of a multi-layered mask, in accordance with an embodiment of the present invention; and

FIG. 7 illustrates a block diagram of an exemplary computer system which controls automated performance of one or more operations in the masking, laser scribing, plasma dicing methods described herein, in accordance with an embodiment of the present invention.

### DETAILED DESCRIPTION

Methods and apparatuses for dicing substrates are described. In the following description, numerous specific details are set forth, such as femtosecond laser scribing and deep silicon plasma etching conditions in order to describe exemplary embodiments of the present invention. However, it will be apparent to one skilled in the art that embodiments of the present invention may be practiced without these specific details. In other instances, well-known aspects, such as IC fabrication, substrate thinning, taping, etc., are not described in detail to avoid unnecessarily obscuring embodiments of the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments. Also, it is to be understood that the various exemplary embodiments shown in the figures are merely illustrative representations and are not necessarily drawn to scale.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” my be used to indicate that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one material layer with respect to other material layers. As such, for example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in contact with that second layer. Additionally, the relative position of one layer with respect to other layers is provided assuming operations are performed relative to a substrate without consideration of the absolute orientation of the substrate.

Generally, a substrate dicing process involving at least an initial laser scribe and potentially a subsequent plasma etch is implemented with a laser energy absorbing water-soluble mask for die singulation. The laser scribe process may be used to cleanly remove an unpatterned (e.g., blanket) mask including the laser energy absorbing water-soluble mask material, a passivation layer, and subsurface thin film device layers along streets between adjacent ICs. The laser ablation process may then either be terminated upon exposure, partial ablation, or complete ablation of the underlying substrate. Where only partial ablation of substrate is performed (e.g., where the wafer is over 100-150 μm), the plasma etch portion of a hybrid dicing process then etches through the bulk of the substrate, such as through bulk single crystalline silicon, for singulation or dicing of chips.

In accordance with an embodiment of the present invention, a combination of laser scribing and plasma etching is used to dice a semiconductor substrate into individualized or singulated ICs. In one embodiment, femtosecond laser scribing is an essentially, if not completely, a non-equilibrium process. For example, the femtosecond-based scribing employing the green band of visible light (e.g., 500-540) may be localized with a negligible thermal damage zone. In an embodiment, laser scribing is used to singulate ICs having ultra-low κ films (i.e., with a dielectric constant below 3.0). In one embodiment, direct writing with a laser eliminates a lithography patterning operation, allowing the masking material to be something other than a conventional photo resist as is used in photolithography. In one embodiment, substantially anisotropic etching is used to complete the dicing process in a plasma etch chamber; the anisotropic etch achieving a high directionality into the substrate by depositing an etch polymer on sidewalls of the etched trench.

FIG. 1 is a flow diagram illustrating a hybrid laser ablation-plasma etch singulation process 101 employing a laser energy absorbing water-soluble mask, in accordance with an embodiment of the present invention. FIG. 2 is a flow diagram illustrating a laser ablation singulation process 201 employing a laser energy absorbing water-soluble mask, in accordance with an embodiment of the present invention. FIGS. 4A-4D illustrate cross-sectional views of a substrate 406 including first and second ICs 425, 426 corresponding to the operations in either method 101 or 201, in accordance with embodiments of the present invention.

Referring to operation 102 of FIGS. 1 and 2, and corresponding FIG. 4A, a laser energy absorbing water-soluble mask material 402A is formed above a substrate 406. Generally, the substrate 406 is composed of any material suitable to withstand a fabrication process of the thin film device layers formed thereon. For example, in one embodiment, the substrate 406 is a group IV-based material such as, but not limited to, monocrystalline silicon, germanium or silicon/germanium. In another embodiment, the substrate 406 is a III-V material such as, e.g., a III-V material substrate used in the fabrication of light emitting diodes (LEDs). During device fabrication, the substrate 406 is typically 600 μm-800 μm thick, but as illustrated in FIG. 4A may have been thinned to 100 μm or even to 50 μm with the thinned substrate now supported by a carrier 411, such as a backing tape 410 stretched across a support structure of a dicing frame (not illustrated) and adhered to a backside of the substrate with a die attach film (DAF) 408.

In embodiments, the first and second ICs 425, 426 include memory devices or complimentary metal-oxide-semiconductor (CMOS) transistors fabricated in a silicon substrate 406 and encased in a dielectric stack. A plurality of metal interconnects may be formed above the devices or transistors, and in surrounding dielectric layers, and may be used to electrically couple the devices or transistors to form the ICs 425, 426. Materials making up the street 427 may be similar to or the same as those materials used to form the ICs 425, 426. For example, street 427 may include thin film layers of dielectric materials, semiconductor materials, and metallization. In one embodiment, the street 427 includes a test device similar to the ICs 425, 426. The width of the street 427 may be anywhere between 10 μm and 200 μm, measured at the thin film device layer stack/substrate interface.

In embodiments, the mask 402A is a laser energy absorbing water-soluble polymer formed at operation 102 in direct contact with a top surface of the ICs 425, 426. For example, the laser energy absorbing water-soluble polymer may be applied directly on a passivation layer, such as a polyimide (PI) top passivation layer of the ICs 425, 426. The mask 402A also covers the intervening street 427 between the ICs 425, 426. The composition of the mask 402A absorbs energy in the UV band in one embodiment, particularly between the 300 and 400 nm wavelengths. In further embodiments, composition of the mask 402A also absorbs energy in the green band (e.g., 500-540 nm).

The mask 402A is unpatterned prior to the laser scribing operation 103 with the laser scribe to perform a direct writing of the scribe lines. As shown in FIG. 3A, where a mask 302A having little absorbance within the laser light band (i.e., substantially transparent in the 300-540 nm band) is disposed over the IC thin film layers 404, the mask 302A may couple very little energy from the laser. Polyvinyl alcohol (PVA), as an exemplary water-soluble mask material having advantageously high water solubility, is highly transparent in the 350 nm to 800 nm range (i.e., non-laser energy absorbing). With most industrial solid state lasers producing photons in the wavelength regime from 250 nm to 1600 nm, a PVA mask passes most laser energy through to the underlying IC thin film layers 404, which having greater absorbance themselves, ablate/vaporize below the surface of the transparent mask. Thus, in FIG. 3A, the thin film IC layer 404 is ablated first, after the laser energy passes through the non-absorbing mask 302A. With the mask 302A unaffected by the laser energy, the mask 302A proximate to the path of the laser is removed as collateral laser scribe damage occurring through secondary, uncontrolled mechanisms which have been found to result in poor quality scribed sidewalls. The inventors have further attributed the rough, fractured sidewalls associated with low mask absorption with low die strength and increased die cracking resulting in potential yield loss.

In contrast, as shown in FIG. 3B, where the laser energy absorbing water-soluble mask 402A is disposed over the IC thin film layers 404, significant laser energy is coupled from a laser upon exposure and the mask 402A ablates/vaporizes no later than does the IC film layer 404. Thus, in FIG. 3B, the mask 402A is itself ablated without extensive collateral laser scribe damage, and scribe sidewall quality/die strength is improved. Notably, ablation of the mask itself, as a temporary layer disposed above the IC film layer 404, has been found important in the quality of scribe in the IC film layer 404. Not intending to be bound by theory, it is currently understood by the inventors that the mechanical forces associated with collateral damage to the mask layer may permanently impair the structure of the IC film layer 404. With this reasoning, UV or green band absorption in the mask 402A is advantageous, and while many UV/green absorptive materials are known in the art, in the exemplary embodiment this property is advantageously obtained without sacrificing the ability to remove the mask 404 with a water-based clean.

In further embodiments, the mask 402A, as a laser energy absorbing water-soluble material is of a composition that further offers some protection to the top surface of the ICs 425, 426 during a hybrid laser ablation-plasma etch singulation process 101 (FIG. 1). However, where the laser energy absorbing water-soluble material has insufficient etch resistance, a second mask layer may be applied as an overcoat of the mask 402A (e.g., as a plasma resistant mask layer, not depicted). Then, with laser energy absorbing mask layer material being water-soluble, the first mask material layer 402A may function either as a means of undercutting the plasma resistant mask layer so that the plasma resistant layer may be lifted off from the underlying IC thin film layer 404, or as a barrier protecting the IC thin film layer 404 from the process used to strip the plasma resistant mask layer. The material composition and thickness of the plasma resistant mask layer may be freely designed to survive the plasma etch process without being constrained to also be water-soluble, or otherwise constrained by mask stripping requirements. In advantageous embodiments, the plasma resistant mask layer 402B is photoresist or PI, either of which is laser energy absorbing and therefore will ablate at least as well as the laser energy absorbing water-soluble mask 402A.

FIG. 5 illustrates an expanded cross-sectional view 500 of one exemplary embodiment including a laser energy absorbing water-soluble mask material layer 402A in contact with a top surface of the IC 426 and the street 427. As shown in FIG. 5, the substrate 406 has a top surface 503 upon which thin film device layers are disposed which is opposite a bottom surface 502 which interfaces with the DAF 408 (FIG. 4A). Generally, the thin film device layer materials may include, but are not limited to, organic materials (e.g., polymers), metals, or inorganic dielectrics such as silicon dioxide and silicon nitride. The exemplary thin film device layers illustrated in FIG. 5 include a silicon dioxide layer 504, a silicon nitride layer 505, copper interconnect layers 508 with low-K (e.g., less than 3.5) or ultra low-κ (e.g., less than 3.0) interlayer dielectric layers (ILD) 507, such as carbon doped oxide (CDO), disposed there between. A top surface of the IC 426 includes a bump 512, typically copper, surrounded by a passivation layer 511, typically a polyimide (PI) or similar polymer. The bumps 512 and passivation layer 511 therefore make up a top surface of the IC with the thin film device layers forming subsurface IC layers. The bump 512 extends from a top surface of the passivation layer 511 by a bump height H_{B}, which in the exemplary embodiments ranges between 10 μm and 50 μm.

Referring to FIG. 5, in the street, the maximum thickness Tₘₐₓ of the laser energy absorbing water-soluble mask 402A in the street 427 is generally limited by the ability of a laser to pattern through the mask by ablation. The laser energy absorbing water-soluble mask 402A may be much thicker over the ICs 425, 426 and or edges of the street 427 where no street pattern is to be formed. As such, T_{MAX} is a function of laser power and the optical conversion efficiency associated with laser wavelength. As T_{MAX} is associated with the street 427, street feature topography, street width, and the method of applying the laser energy absorbing water-soluble mask 402A may be designed to limit T_{MAX} to a thickness which can be ablated along with underlying thin film device layers in one or more laser passes, depending on throughput requirements. In particular embodiments, the laser energy absorbing water-soluble mask 402A has a street mask thickness T_{MAX} that is less than 30 μm and advantageously less than 20 μm with a thicker mask calling for multiple laser passes.

As further shown in FIG. 5, the minimum thickness T_{MIN} of the laser energy absorbing water-soluble mask 402A, found on a top surface of the bump 512 (being an extreme of the topography), is a function of the selectivity achieved by the subsequent plasma etch (e.g., operation 105 in FIG. 1). The plasma etch selectivity is dependent on at least both the material/composition of the laser energy absorbing water-soluble mask 402A and the etch process employed.

As oxidative plasma cleans, acidic etchants, and many other conventional mask stripping processes may not be compatible with the bump 512 and/or passivation layer 511, laser energy absorbing water-soluble mask 402A is advantageously a polymer soluble in water. In a further embodiment, the laser energy absorbing water-soluble mask 402A is also thermally stable to at least 60° C., preferably stable at 100° C., and ideally stable to 120° C. to avoid excessive crosslinking (i.e., thermal curing) during the subsequent plasma etch process when the material's temperature will be elevated (e.g., through application of plasma power). In alternative embodiments however, thermal curing may be acceptable because depending on the polymers present, crosslinking may either disadvantageously reduce the water solubility of the mask material, or as is typical of some UV curable adhesive films, may advantageously reduce adhesion forces between the mask 402A and the IC thin film layers 404 (e.g., by 80%, or more), potentially making subsequent removal of the mask 402A more, or less, difficult.

Exemplary laser energy absorbing water-soluble materials include polymer materials possessing unsaturated hydrocarbon side chains with C═C double bonds, which are absorbing in the 300-540 nm band. Exemplary materials include photo-active compounds that may be employed for UV-initiated (or green band-initiated) crosslinking. In one exemplary embodiment, the mask 402A is a photo-reactive water-soluble polymer material including one or more photo-active compound, such as, but not limited to 4-acrloyloxy benzophenon (ABP). Because a UV-curable material is photo-reactive within the 300-400 nm band in the presence of appropriate co-reactants, undergoing cross-linking upon exposure to UV light, the material demonstrates much higher UV absorbance than PVA, particularly prior to UV curing. While a material with UV absorbance does not necessarily absorb well at 500-540 nm, it is likely to also perform adequately for lasers operating in the green band as well. Thus, in certain embodiments the laser energy absorbing water-soluble mask 402A is a “UV-curable,” but not a “UV-cured” material, that is water-soluble at least in the UV-curable state even if not so in the UV-cured state. In embodiments where a “photocrosslinkable,” but not “photocrosslinked” material is employed, photocrosslinking may actually be avoided throughout the processes 101 and 201 in all regions of the mask 402A that are not ablated by the laser where photo emission during plasma etching of the substrate is insufficient to cure the mask 402A. In this manner even where a photocrosslinked material would have poor water solubility, unreacted photocrosslinkable material beyond the scribe line may retain good water solubility while the presence of the photo-active compound improves the UV absorption characteristics of the mask for favorable mask ablation.

In embodiments, the UV-curable material is synthesized from soluble “hard” monomers, like acrylic acid (AA) or Beta-acryloyloxy propionic acid (APA), and may further be a copolymer reaction product additionally including insoluble, “soft” monomers, like butylacrylate (BA). Notably, the solubility of copolymer materials such as the AA-BA example is a function of their proportions, and therefore stripping of the mask may be engineered as necessary, constrained only by potential dependence of UV absorbance on the relative proportion of soft and hard monomers.

In another embodiment, the UV-curable material is a photocrosslinkable PVA derivative, such as, but not limited to poly(vinyl alcohol), N-methyl-4(4′-formylstyryl)pyridinium methosulfate acetal (SbQ-PVA). SbQ-PVA is another example of a photocrosslinkable polymer that is water-soluble at least prior to crosslinking. In this embodiment as well, the cross-linking reaction is induced through absorbance of photons in the UV band and therefore also ensures mask ablation will be superior to that of a UV-transparent PVA. As a fully cured form of SbQ-PVA is may have significantly lower water solubility than the uncured form, this embodiment exemplifies a system where it is advantageous to avoid curing during a subsequent plasma etch (e.g., operation 105 in FIG. 1), or avoid the plasma etch all together as in FIG. 2. Logic similar to that applied above for selection of UV-curable materials may be applied more specifically for materials that will absorb in the green band.

In one embodiment, the laser energy absorbing mask material includes materials such as those described above, but with the addition of iron or other metal particles in the mask material. In one such embodiment, the iron or other metal particles increase the mask's absorption of the laser radiation.

Generally, the laser energy absorbing water-soluble mask may be applied in any conventional manner, such as spin application with the polymer diluted in water, for example. In a spin application, a substrate is loaded onto a spin coat system or transferred into a spin coat module of an integrated platform and a polymeric precursor solution is spun over the passivation layer 511 and bump 512. The wet coat is then dried or baked, for example on a hot plate, and the substrate is unloaded for laser scribe or transferred in-vaccuo to a laser scribe module. For embodiments where the first mask material layer 402A is hygroscopic, in-vaccuo transfer is advantageous. The spin and dispense parameters are a matter of choice depending on the material, substrate topography, and desired first mask material layer thickness. The bake temperature and time may be selected to avoid excessive crosslinking if such would render removal difficult. Exemplary drying temperatures ranging from 60° C. to 150° C., depending on the material. The mask may also be formed with other techniques, such as lamination techniques. In one such embodiment, a dry film is applied to a surface of the semiconductor wafer using a dry film vacuum lamination technique.

Returning now to operation 103 of method 101, and corresponding FIG. 4B, the mask 402A is patterned by ablation with a laser scribing process forming trenches 412, extending the subsurface thin film device layers, and exposing regions of the substrate 406 between the ICs 425, 426. As such, the laser scribing process is used to ablate the thin film material of the streets 427 originally formed between the ICs 425, 426. In accordance with an embodiment of the present invention, patterning the laser energy absorbing water-soluble mask 402A with the laser-based scribing process includes forming trenches 414 partially into the regions of the substrate 406 between the ICs 425, 426, as depicted in FIG. 4B.

In the exemplary embodiment illustrated in FIG. 5, the laser scribing depth D_{L} is approximately in the range of 5 μms to 50 μms deep, advantageously in the range of 10 μms to 20 μms deep, depending on the thickness T_{F} of the passivation layer 511, subsurface thin film device layers, and the thickness T_{MAX} of the mask 402A.

In an embodiment, the mask 402A is patterned with a laser having a pulse width (duration) in the femtosecond range (i.e., 10⁻¹⁵ seconds), referred to herein as a femtosecond laser. Laser parameters selection, such as pulse width, may be critical to developing a successful laser scribing and dicing process that minimizes chipping, microcracks and delamination in order to achieve clean laser scribe cuts. A laser frequency in the femtosecond range advantageously mitigates heat damage issues relative longer pulse widths (e.g., picosecond or nanosecond). Although not bound by theory, as currently understood a femtosecond energy source avoids low energy recoupling mechanisms present for picosecond sources and provides for greater thermal nonequilibrium than does a nanosecond-source. With nanosecond or picosecond laser sources, the various thin film device layer materials present in the street 427 behave quite differently in terms of optical absorption and ablation mechanisms. For example, dielectrics layers such as silicon dioxide, is essentially transparent to all commercially available laser wavelengths under normal conditions. By contrast, metals, organics (e.g., low-K materials) and silicon can couple photons very easily, particularly nanosecond-based or picosecond-based laser irradiation. If non-optimal laser parameters are selected, in a stacked structures that involve two or more of an inorganic dielectric, an organic dielectric, a semiconductor, or a metal, laser irradiation of the street 427 may disadvantageously cause delamination. For example, a laser penetrating through high bandgap energy dielectrics (such as silicon dioxide with an approximately of 9 eV bandgap) without measurable absorption may be absorbed in an underlying metal or silicon layer, causing significant vaporization of the metal or silicon layers. The vaporization may generate high pressures potentially causing severe interlayer delamination and microcracking. Femtosecond-based laser irradiation processes have been demonstrated to avoid or mitigate such microcracking or delamination of such material stacks.

Parameters for a femtosecond laser-based process may be selected to have substantially the same ablation characteristics for the inorganic and organic dielectrics, metals, and semiconductors. For example, the absorptivity/absorptance of silicon dioxide is non-linear and may be brought more in-line with that of organic dielectrics, semiconductors and metals. In one embodiment, a high intensity and short pulse width femtosecond-based laser process is used to ablate a stack of thin film layers including a silicon dioxide layer and one or more of an organic dielectric, a semiconductor, or a metal. In accordance with an embodiment of the present invention, suitable femtosecond-based laser processes are characterized by a high peak intensity (irradiance) that usually leads to nonlinear interactions in various materials. In one such embodiment, the femtosecond laser sources have a pulse width approximately in the range of 10 femtoseconds to 500 femtoseconds. In one embodiment, the pulse width is in the range of approximately 50 femtoseconds to 400 femtoseconds.

In certain embodiments, the laser emission spans any combination of the visible spectrum, the ultra-violet (UV), and/or infra-red (IR) spectrums for a broad or narrow band optical emission spectrum. Even for femtosecond laser ablation, certain wavelengths may provide better performance than others. For example, in one embodiment, a femtosecond-based laser process having a wavelength close to (e.g., green band), or in, the UV band provides a cleaner ablation process than a femtosecond-based laser process having a wavelength closer to or in the IR range. In a specific embodiment, a femtosecond laser suitable for semiconductor substrate or substrate scribing is based on a laser having a wavelength of approximately less than or equal to 540 nanometers, although preferably in the range of 540 nanometers to 250 nanometers. In a particular embodiment, pulse widths are less than or equal to 500 femtoseconds for a laser having a wavelength less than or equal to 540 nanometers. However, with some laser energy absorbing water soluble masks, a less expensive and more powerful infrared femtosecond laser may be employed rather than the more expensive more complicated second harmonic femtosecond lasers at 500-550 nm regime which only have 40-60% laser power of the infrared laser versions. In still other embodiments, dual laser wavelengths (e.g., a combination of an IR laser and a UV laser) are used.

In one embodiment, the laser and associated optical pathway provide a focal spot at the work surface approximately in the range of 3 μm to 15 μm, though advantageously in the range of 5 μm to 10 μm. The spatial beam profile at the work surface may be a single mode (Gaussian) or have a beam shaped top-hat profile. In an embodiment, the laser source has a pulse repetition rate approximately in the range of 300 kHz to 10 MHz, although preferably approximately in the range of 500 kHz to 5 MHz. In an embodiment, the laser source delivers pulse energy at the work surface approximately in the range of 0.5 μJ to 100 μJ, although preferably approximately in the range of 1 μJ to 5 μJ. In an embodiment, the laser scribing process runs along a work piece surface at a speed approximately in the range of 500 mm/sec to 5 msec, although preferably approximately in the range of 600 mm/sec to 2 msec.

The scribing process may be run in single pass only, or in multiple passes, but is advantageously no more than two passes. The laser may be applied either in a train of single pulses at a given pulse repetition rate or a train of pulse bursts. In an embodiment, the kerf width of the laser beam generated is approximately in the range of 2 μm to 15 μm, although in silicon substrate scribing/dicing preferably approximately in the range of 6 μm to 10 μm, as measured at a device/silicon interface.

Returning to FIGS. 1 and 4C, the substrate 406 is etched through the trenches 412 in the patterned mask 402A to singulate the ICs 425, 426. In accordance with an embodiment of the present invention, etching the substrate 406 includes etching the trenches 412 formed with the femtosecond-based laser scribing process to ultimately etch entirely through substrate 406, as depicted in FIG. 4C.

In an embodiment, etching the substrate 406 includes using an anisotropic plasma etching process 416. In one embodiment, a through substrate etch process is used with the mask 402A (and any potential overcoat) from plasma exposure for the entire duration of plasma etch. A high-density plasma source operating at high powers may be used for the plasma etching operation 105. Exemplary powers range between 3 kW and 6 kW, or more to achieve an etch rate of the substrate 406 that is greater than 25 μms per minute.

In an exemplary embodiment, a deep anisotropic silicon etch (e.g., a through silicon via etch) is used to etch a single crystalline silicon substrate or substrate 406 at an etch rate greater than approximately 40% of conventional silicon etch rates while maintaining essentially precise profile control and virtually scallop-free sidewalls. Effects of the high power on the mask 402A may be controlled through application of cooling power via an electrostatic chuck (ESC) chilled to −10° C. to −15° C. to maintain the mask material at a temperature below 100° C. and preferably between 70° C. and 80° C. throughout the duration of the plasma etch process. At such temperatures, solubility of the laser energy absorbing water-soluble mask material 402A may be advantageously maintained.

In a specific embodiment, the plasma etch entails a plurality of protective polymer deposition cycles interleaved over time with a plurality of etch cycles. The deposition:etch duty cycle may vary with the exemplary duty cycle being approximately 1:1. For example, the etch process may have a deposition cycle with a duration of 250 ms-750 ms and an etch cycle of 250 ms-750 ms. Between the deposition and etch cycles, an etching process chemistry, employing for example SF₆ for the exemplary silicon etch embodiment, is alternated with a deposition process chemistry, employing a polymerizing CₓF_{y} gas such as, but not limited to, CF₄, C₄F₆ or C₄F₈. Process pressures may further be alternated between etch and deposition cycles to favor each in the particular cycle, as known in the art.

The singulation methods 101 and 102 are then completed at operation 107 with removal of the mask 402A. In the exemplary embodiment illustrated in FIG. 4D, the mask removal operation 107 entails dissolving the mask 402A selectively to the ICs 425, 426 (e.g., selectively to passivation layer 511, bump 512). In one embodiment, the water-soluble mask layer 402A is washed off with a pressurized jet of de-ionized water or through submergence of the substrate in an ambient or heated water bath. For embodiments where the laser energy absorbing water-soluble mask 402A remains photon-curable and/or otherwise photocrosslinkable after the dicing process and the mask composition is of the type that such curing/crosslinking reduces the adhesion force of the remaining mask to bumps or pillars on the IC, the mask 402A may be cured after dicing at an appropriate wavelength (e.g., UV), or cured thermally. In still other embodiments, after curing and water-wetting the remaining mask 402A, another adhesive layer, such as a dicing tape, is attached atop the remaining mask 402A and then peeled off with the remaining mask.

As further illustrated in FIG. 4D, either of the singulation process or mask removal process may further include patterning the die attach film 408, exposing the top portion of the backing tape 410.

A single integrated platform 600 may be configured to perform many or all of the operations in the hybrid laser ablation-plasma etch singulation process 101. For example, FIG. 6 illustrates a block diagram of a cluster tool 606 coupled with laser scribe apparatus 610 for laser and plasma dicing of substrates, in accordance with an embodiment of the present invention. Referring to FIG. 6, the cluster tool 606 is coupled to a factory interface 602 (FI) having a plurality of load locks 604. The factory interface 602 may be a suitable atmospheric port to interface between an outside manufacturing facility with laser scribe apparatus 610 and cluster tool 606. The factory interface 602 may include robots with arms or blades for transferring substrates (or carriers thereof) from storage units (such as front opening unified pods) into either cluster tool 606 or laser scribe apparatus 610, or both.

A laser scribe apparatus 610 is also coupled to the FI 602. In an embodiment, the laser scribe apparatus 610 includes a femtosecond laser operating in the 300-540 nm band. The femtosecond laser is configured to perform the laser ablation portion of the hybrid laser and etch singulation process 101. In one embodiment, a moveable stage is also included in laser scribe apparatus 610. The moveable stage is configured for moving a substrate or substrate (or a carrier thereof) relative to the femtosecond-based laser. In a specific embodiment, the femtosecond laser is also moveable.

The cluster tool 606 includes one or more plasma etch chambers 608 coupled to the FI by a robotic transfer chamber 650 housing a robotic arm for in-vaccuo transfer of substrates. The plasma etch chambers 608 are suitable for performing a plasma etch portion of the hybrid laser and etch singulation process 101. In one exemplary embodiment, the plasma etch chamber 608 is further coupled to an SF₆ gas source and at least one of a CF₄, C₄F₈ and C₄F₆ source. In a specific embodiment, the one or more plasma etch chambers 608 is an Applied Centura® Silvia™ Etch system, available from Applied Materials of Sunnyvale, Calif., USA, although other suitable etch systems are also available commercially. In an embodiment, more than one etch chamber 608 is included in the cluster tool 606 portion of integrated platform 600 to enable high manufacturing throughput of the singulation or dicing process.

The cluster tool 606 may include other chambers suitable for performing functions in the hybrid laser ablation-plasma etch singulation process 101. In the exemplary embodiment illustrated in FIG. 6, the cluster tool 606 includes both a mask formation module 612 and a wet station 614, though either may be provided in absence of the other. The mask formation module 612 may be a spin coating module. As a spin coating module, a rotatable chuck is configured to clamp by vacuum, or otherwise, a thinned substrate mounted on a carrier such as backing tape mounted on a frame. In further embodiments, the spin coating module is fluidly coupled to an aqueous solution source.

Embodiments of the wet station 614 are to dissolve the mask material layer 402A after plasma etching the substrate. The wet station 614 may include for example a pressurized spray jet to dispense water other solvent.

FIG. 7 illustrates a computer system 700 within which a set of instructions, for causing the machine to execute one or more of the scribing methods discussed herein may be executed, for example to analyze a reflected light from a tag to identify at least one micromachine artifact. The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, etc. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations and steps discussed herein.

The computer system 700 may further include a network interface device 708. The computer system 700 also may include a video display unit 710 (e.g., a liquid crystal display (LCD) or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 731 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

The machine-accessible storage medium 731 may also be used to store pattern recognition algorithms, artifact shape data, artifact positional data, or particle sparkle data. While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

Thus, methods of dicing semiconductor substrates, each substrate having a plurality of ICs, have been disclosed. The above description of illustrative embodiments of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize. The scope of the invention is therefore to be determined entirely by the following claims, which are to be construed in accordance with established doctrines of claim interpretation.

What is claimed is:

1. A method of dicing a substrate comprising a plurality of ICs, the method comprising:
forming a laser energy absorbing water-soluble mask over the substrate covering and protecting the ICs;
patterning the mask with a laser scribing process to provide a patterned mask with gaps, exposing regions of the substrate between the ICs, wherein the mask absorbs photons within an operating band of a laser used to pattern the mask; and
plasma etching the substrate through the gaps in the patterned mask to singulate the ICs.

2. The method of claim 1, wherein forming the water-soluble mask further comprises depositing a UV-curable water-soluble polymeric precursor over the ICs.

3. The method of claim 2, wherein the UV-curable water-soluble polymeric precursor comprises a photo-active compound that induces polymer crosslinking upon exposure to energy in the 300-400 nm band.

4. The method of claim 3, wherein the laser energy absorbing water-soluble mask is not UV-cured prior to the laser scribing process.

5. The method of claim 4, wherein a portion of the laser energy absorbing water-soluble mask remaining after the laser scribing process is substantially uncured.

6. The method of claim 5, wherein the laser energy absorbing water-soluble mask has higher water solubility in an uncured state than in a cured state and wherein the portion of the laser energy absorbing water-soluble mask remaining after plasma etching is substantially uncured.

7. The method of claim 1, wherein the forming the mask comprises applying at least one of: a photocrosslinkable PVA derivative, or photocrosslinkable soluble “hard” monomers, copolymerized with insoluble, “soft” monomers.

8. The method of claim 1, wherein patterning the mask further comprises direct writing the pattern with a femtosecond laser.

9. The method of claim 1, wherein forming the mask comprises:
spin coating a solution of a laser energy absorbing water-soluble polymer onto a top surface of the ICs; and
drying the solution.

10. The method of claim 1, further comprising:
removing the mask with an aqueous solution.

11. A semiconductor wafer comprising:
a plurality of ICs disposed on a substrate; and
a laser energy absorbing water-soluble mask disposed over thin film layers of the ICs, the mask ablated in regions disposed over streets between adjacent ICs.

12. The semiconductor wafer of claim 11, wherein the laser energy absorbing water-soluble mask comprises a UV-curable water-soluble polymer.

13. The semiconductor wafer of claim 12, wherein the UV-curable water-soluble polymer comprises a photocrosslinkable PVA derivative, or photocrosslinkable soluble “hard” monomers, copolymerized with insoluble, “soft” monomers.

14. The semiconductor wafer of claim 11, wherein a non-ablated portion of the laser energy absorbing water-soluble mask is substantially uncured.

15. The semiconductor wafer of claim 14, wherein the laser energy absorbing water-soluble mask has higher water solubility in an uncured state than in a cured state and wherein the non-ablated portion of the laser energy absorbing water-soluble mask is substantially uncured.

16. A system for dicing a substrate comprising a plurality of ICs, the system comprising:
a laser scribe module to pattern a mask and expose regions of the substrate between the ICs;
a plasma etch chamber physically coupled to the laser scribe module to singulate the ICs by plasma etching of the substrate;
a robotic transfer chamber to transfer a laser scribed substrate from the laser scribe module to the plasma etch module, and
a mask formation module comprising a spin coater coupled to a UV-curable water soluble polymeric precursor and configured to form a laser energy absorbing water-soluble mask over the substrate.

17. The system of claim 16, wherein the laser scribe module comprises a femtosecond laser.

18. The system of claim 16, wherein the plasma etch chamber is coupled to SF₆ and at least one of CF₄, C₄F₈, and C₄F₆.

19. The system of claim 16, wherein the UV-curable water soluble polymeric precursor comprises a photo-active compound that induces polymer crosslinking upon exposure to energy in the 300-400 nm band.

20. The system of claim 16, further comprising:
a wet station configured to remove the mask with an aqueous solution.
